(19) United States
(12) Patent Application Publication
(10) Pub. No.: US 2005/0073671 A1
(43) Pub. Date: Apr. 7, 2005

(54) Composite optical lithography method for patterning lines of substantially equal width

(75) Inventor: Yan Borodovsky, Portland, OR (US)

Correspondence Address: FISH & RICHARDSON, PC, 12390 EL CAMINO REAL, SAN DIEGO, CA, 92130-2081, US

(73) Assignee: Intel Corporation

(21) Appl. No.: 10/681,031

(22) Filed: Oct. 7, 2003

(51) Int. Cl. G03F 9/00; G03B 27/00; G03F 7/20

(52) U.S. Cl. 355/77; 430/5; 430/313; 430/394; 430/396; 355/18

(57) ABSTRACT

A composite patterning technique may include two lithography processes. A first lithography process may use interference lithography to form a continuous pattern of lines of substantially equal width on a photoresist. A second lithography process may use one or more non-interference lithography techniques, such as optical lithography, imprint lithography and electron-beam lithography, to break continuity of the patterned lines and form desired integrated circuit features.

### BACKGROUND

An integrated circuit (IC) manufacturing process may deposit various material layers on a wafer and form a photosensitive resist (photoresist) on the deposited layers. The process may use lithography to transmit light through or reflect light from a patterned reticle (mask) to the photoresist. Light from the reticle transfers a patterned image onto the photoresist. The process may remove portions of the photoresist which are exposed to light. A process may etch portions of the wafer which are not protected by the remaining photoresist to form integrated circuit features.

The semiconductor industry may continually strive to reduce the size of transistor features to increase transistor density and to improve transistor performance. This desire has driven a reduction in the wavelength of light used in photolithographic techniques to define smaller IC features in a photoresist. Complex lithographic exposure tools may cost more to make and operate.

A conventional patterning technique may use expensive, diffraction-limited, high numerical aperture (NA), highly aberration corrected lens/tools equipped with complex illumination. A conventional patterning technique may also use complicated and expensive masks, which employ various phase shifters and complex optical proximity (OPC) corrections.

### BRIEF DESCRIPTION OF DRAWINGS

FIG. 1A illustrates an interference lithography apparatus.

FIG. 1B illustrates an example of a diffraction grating with slits which allow light to pass through and radiate a photoresist on a substrate.

FIG. 2 illustrates a latent or real image of a pattern of spaces and lines produced by the interference lithography apparatus of FIG. 1A or by projecting an image of a grating in FIG. 1B through projection optics onto the substrate.

FIG. 3A illustrates an example of a desired layout of integrated circuit features formed by an interference lithography process and a second lithography process.

FIG. 3B illustrates an example of the second lithography process layout which may expose desired areas of the photoresist to radiation, which breaks continuity of the patterned lines of FIG. 2 to produce the desired layout of FIG. 3A.

FIGS. 4A-4H illustrate an example of a second lithography process to expose areas on a photoresist and subsequent processes of developing, etching and stripping.

FIG. 5 illustrates a composite optical lithography exposure system with a movable wafer stage.

FIG. 6 shows an optical lithographic implementation of the second patterning system.

FIG. 7 is a flow chart of the composite optical lithography patterning technique.

FIG. 8 shows a process for generating a layout of a mask for the second lithography process.

FIG. 9 shows an example of a design layout.

FIG. 10 shows an example of a remainder layout.

FIG. 11 shows a remainder layout after an expansion in a direction D.

### DETAILED DESCRIPTION

The present application relates to a composite optical lithography patterning technique, which may form smaller integrated circuit features compared to conventional lithography techniques. The composite patterning technique may provide a high density of integrated circuit features for a given area on a substrate.

The composite patterning technique may include two lithography processes. A first lithography process uses a radiation source and an interference lithography apparatus to form a pattern of alternating lines and spaces on a photosensitive media. A second lithography process may use one or more non-interference lithography techniques, such as projection optical lithography, imprint lithography and electron-beam (e-beam) lithography, to break continuity of the patterned lines and form desired integrated circuit features.

In another embodiment, the first process may include a non-interference lithography technique, and the second process may include an interference lithography technique.

First Lithography Process

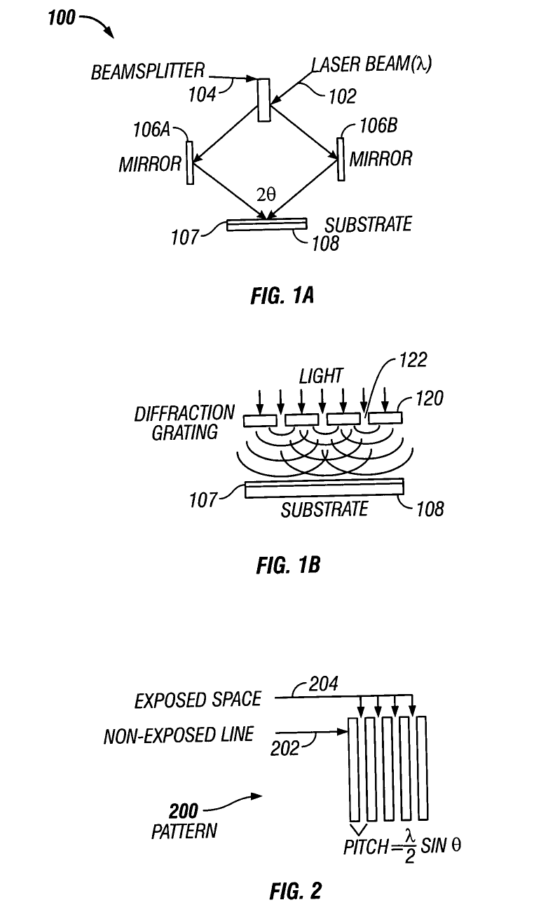

FIG. 1A illustrates an interference (interferometric) lithography apparatus 100. The interference lithography apparatus 100 may include a beam splitter 104 and two mirrors 106A, 106B. The beam splitter 104 may receive radiation, such as conditioned (expanded and collimated) laser beam 102, from a radiation source with a pre-determined exposure wavelength (X). The beam splitter 104 may direct the radiation 102 to the mirrors 106A, 106B. The mirrors 106A, 106B may form a pattern 200 (FIG. 2) on a substrate 108 with a photosensitive media, such as a photoresist layer 107. Many interferometric lithography tool designs with various complexity and sophistication are available. Either a positive or a negative photoresist may be used with the processes described herein. θ may be an angle between a surface normal of the photoresist 107 and a beam of radiation incident on the photoresist 107.

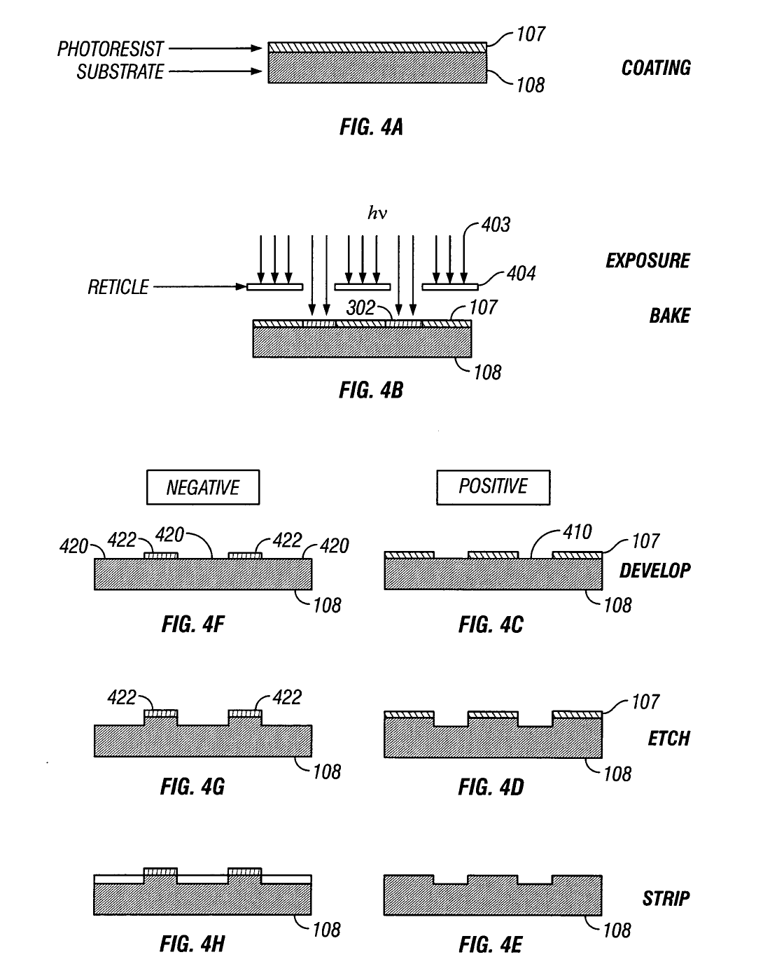

FIG. 2 illustrates a latent or real image of pattern 200 of alternating spaces 204 (exposed to light) and lines 202 (not exposed to light) produced by the interference lithography apparatus 100 of FIG. 1A. “Latent” refers to a pattern on the photoresist 107 which experienced a chemical reaction due to radiation but has not yet been developed in a solution to remove the exposed areas of positive tone photoresist 107 (FIG. 4C described below). The lines 202 may have a substantially equal width. The spaces 204 may or may not have a width equal to the width of the lines 202.

“Pitch” is a sum of a line width and a space width in FIG. 2. As known to those of ordinary skill in optics, a “minimal pitch,” which can be resolved by a projection optical exposure apparatus with a pre-determined wavelength λ and numerical aperture NA, may be expressed as:
pitch/2=(k₁(λ/ni))/NA
“NA” is the numerical aperture of a projection lens in the lithography tool. “ni” is the refractive index of a media between the substrate 108 and the last element of the optical projection system, e.g., mirrors 106A, 106B. Optical projection systems currently in use for microlithography use air, which has ni=1. ni>1.4 for liquid immersion microlithographic systems. For ni=1, the pitch may be expressed as:
pitch/2=k₁λ/NA
pitch=2k₁λ/NA

NA may be expressed as:
NA=n₀sinθ

NA may be equal to 1. k₁ may be known as a Rayleigh's constant.

If k₁=0.25, and no is about equal to one, pitch may expressed as:
pitch=2(0.25)λ/n₀sinθ≈λ/2sinθ

Other values of k₁ may be greater than 0.25.

The interference lithography apparatus 100 of FIG. 1A may achieve a “minimal pitch” (a minimal line width plus space width) expressed as:
minimal pitch≈λ/2

The lines 202 and spaces 204 may have a pitch P₁ approaching λ₁/2, where λ₁ is the radiation wavelength used in the interference lithography process. The wavelength λ₁ may equal to 193 nm, 157 nm or an extreme ultraviolet (EUV) wavelength, such as 11-15 nm or any other wavelength suitable for patterning microlithography patterns with the help of interferometic lithography. Larger pitches may be obtained by changing the angle θ of interfering beams in FIG. 1A.

Minimal feature size of an exposed space 204 or non-exposed line 202 may be equal to, less than or larger than exposure wavelength divided by four (λ/4).

The first (interference lithography) process may define a width of all minimal critical features of a final pattern at a maximum density achievable by means of optical patterning with maximum process latitude.

Instead of the beam splitter 104, any light-splitting or interference element may be used, such as a prism or diffraction grating, to produce a pattern 200 of alternating lines 202 and spaces 204 on the photoresist 107.

FIG. 1B illustrates an example of a diffraction grating 120 with slits 122 which allow light to pass through and radiate a photoresist 107 on a substrate 108. The diffraction grating 120 in conjunction with projection optics may produce the same pattern 200 (FIG. 2) as the beam splitter 104 and mirrors 106A, 106B of FIG. 1A.

The area of the pattern 200 formed by interference lithography may be equal to a die, multiple dies or a whole wafer, e.g., a 300-mm wafer or even larger future generation wafer sizes. Interference lithography may have excellent dimensional control of a pattern 200 due to a large depth of focus.

Interference lithography may have a lower resolution limit and better dimensional control than projection (lens-based) lithography. Interference lithography may have a higher process margin than projection lens-based lithography because depth of focus for interference lithography may be hundreds or thousands of microns, in contrast to a fraction of a micron (e.g., 0.3 micron) depth of focus for some conventional optical lithography techniques. Depth of focus may be important in lithography because focus control of exposure systems at sub-micron level is not sufficiently stable. In addition, the photoresist may not be completely flat because (a) the photoresist is formed over one or more metal layers and dielectric layers or (b) semiconductor wafer itself might not be sufficiently flat.

An embodiment of interference lithography may not need a complicated illuminator, expensive lenses, projection and illumination optics or a complex mask, in contrast to other lithography techniques.

Second Lithography Process

A second lithography process may include one or more non-interference lithography techniques, such as a conventional lithography technique, such as projection optical lithography, imprint lithography and electron-beam (e-beam) lithography. Alternatively, the second lithography process may use extreme ultraviolet (EUV) lithography.

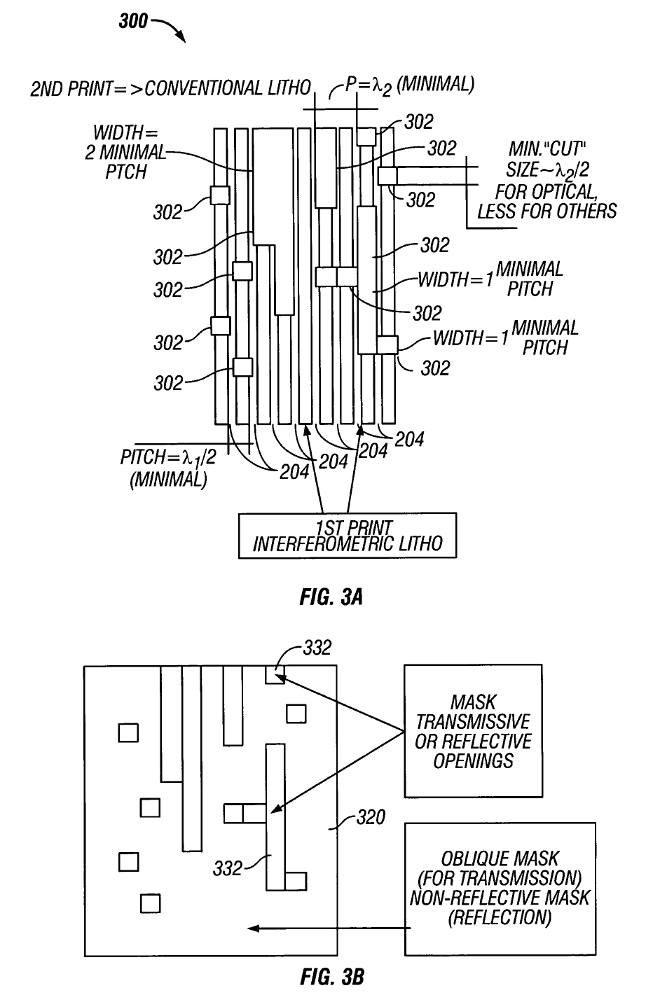

FIG. 3A illustrates an example of a desired layout 300 of integrated circuit features formed by the interference lithography process described above and a selected second lithography process.

FIG. 3B illustrates an example of the second lithography process layout 320 that may expose desired areas 302 of the photoresist 107 to radiation, which breaks continuity of the patterned lines 202 of FIG. 2 to produce the desired layout 300 shown on FIG. 3A. The layout 320 of FIG. 3B may be an oblique mask with transmissive openings 332 for positive resist imaging. Alternatively, the layout 320 of FIG. 3B may be a non-reflective mask with reflective openings 332. A method for making a print mask is described below with reference to FIGS. 8-12.

The second lithography process may remove or erase undesired portions 302 of the lines 202, which were not exposed to light during the first process, by exposing the undesired portions of the lines 202 to radiation. Thus, the spaces 204 and areas 302 in FIGS. 3A-3B are exposed to light during the first and second processes, respectively.

λ₁ may represent a radiation wavelength used in the first (interference) lithography process, and λ₂ represents a radiation wavelength used in the second (conventional) lithography process. For example, the wavelengths λ₁ and λ₂ may each be 193 nm, 157 nm or an extreme ultraviolet (EUV) wavelength, such as 11-15 nm.

The patterning layout of the second lithography process on an exposure mask (or maskless patterning tool database) may be a Boolean difference between (a) a desired final pattern shown in FIG. 3A, which is sized up for desired dimensional and overlay controls for all minimal line-width features, and (b) the diffraction grating pattern 200 (FIG. 2) formed by the first lithography process. Approximate layout of the second process' mask (or its corresponding database for maskless patterning) is shown as areas 302 in FIG. 3B.

As shown in FIG. 3A, the layout 300 formed by the first and second processes may be limited to the minimal pitch (P) of the continuous alternating lines and spaces pattern 200 in FIG. 2 and integer multiples of the minimal pitch (e.g., 1P, 2P, 3P).

FIGS. 4A-4H illustrate an example of a second lithography process to expose areas 302 (FIG. 3) on the photoresist 107 and subsequent processes of developing, etching and stripping. A photoresist 107 may be formed (e.g., coated) on a substrate 108 in FIG. 4A. A latent or real pattern 200 of alternating continuous lines and spaces (unexposed and exposed regions)(FIG. 2) may be formed on the photoresist 107 by the interference lithography apparatus 100 of FIG. 1A. A second lithography tool (second lithography process) may transmit light 403 through a patterned mask or reticle 404 to expose desired areas 302 of the photoresist 107 in FIG. 4B. The light 403 may start a reaction in the exposed areas 302. The light 403 may be Ultraviolet or extreme ultraviolet (EUV) radiation, for example, with a wavelength of about 11-15 nanometers (nm).

The photoresist 107 and substrate 108 may be removed from the lithography tool and baked in a temperature-controlled environment. Radiation exposure and baking may change the solubility of the exposed areas 302 and spaces 204 (FIG. 2) compared to unexposed areas of the photoresist 107. The photoresist 107 may be “developed,” i.e., put in a developer and subjected to an aqueous (H20) based solution, to remove exposed areas 302 and spaces 204 of the photoresist 107 in FIG. 4C to form a desired pattern in the resist. If a “positive” photoresist is used, exposed areas 302 and 204 may be removed by the solution. Portions 410 of the substrate 108 which are not protected by the remaining photoresist 107 may be etched in FIG. 4D to form desired circuit features. The remaining photoresist 107 may be stripped in FIG. 4E.

If a “negative” photoresist is used, areas which are not exposed to radiation may be removed by the developing solution, as shown in FIG. 4F. Then portions 420 of the substrate 108 which are not protected by the remaining photoresist 422 may be etched in FIG. 4G to form desired circuit features. The remaining photoresist 422 may be stripped in FIG. 4H.

To break continuity of lines 202 to form desired layout shown in FIG. 3A, a conventional lithography exposure tool may be used. Integrated circuit layouts customary used in patterning lines produce a pattern with a length-to-width ratio of equal or greater than 1.5:1 (e.g., for a gate layer of a transistor structure). Thus, a conventional exposure tool may be used to form the areas 302 of FIG. 3 because pitch for “along length” areas 302 may be about 1.5 or more times larger than for minimal features, such as the exposed spaces 204. The areas 302 produced by a conventional exposure tool produce a “cut,” which may be reduced further through the use of known RELACS™ or SAFIRE™ size reduction techniques. A simple binary mask with minimal proximity correction may be used in the second lithography process.

For example, 193-nm interference tool may produce a 100-nm pitch grating pattern, while 193-nm or 248 nm or 365 nm optical projection tools may be used for a second lithography process to pattern line-to-line openings.

The second lithography process may use another mask-based technique such as imprint or a maskless patterning technique.

Combining an interference lithography technique and a non-interference technique may provide high IC pattern density scaling (patterning at k1=0.25 for any available wavelength).

Interference lithography, which patterns minimal pitch features, may extend 193-nm immersion lithography to 66-nm pitch and may extend an EUV interference tool capability down to 6.7-nm pitch.

Interference lithography may have an all-reflective design, e.g., Lloyds' mirror interferometric lithographic system, which may enable system design with available wavelengths between 157 nm and 13.4 nm, such as a neon discharge source (about 74-nm wavelength) and a helium discharge source (58.4-nm wavelength) with corresponding minimal pitches of 37 nm and 30 nm, respectively.

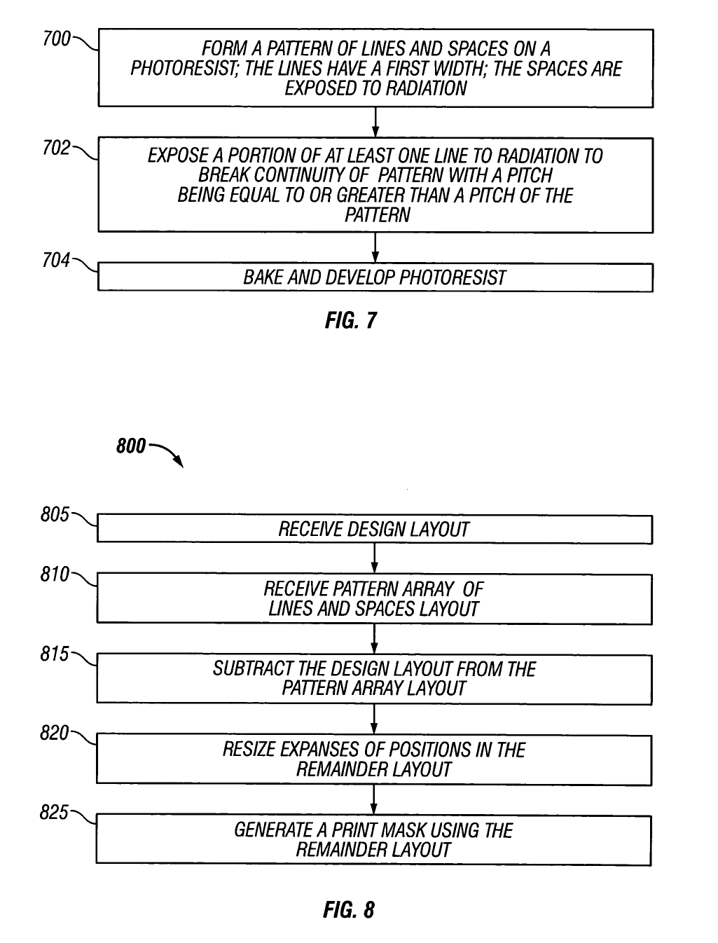

FIG. 7 is a flow chart of the composite optical lithography patterning technique. Interference lithography exposure on a photoresist at 700 may be followed by a second lithography exposure applied to the same photoresist at 702. The photoresist may be baked, and soluble portions of the photoresist may be developed at 704 if the photoresist is sensitive to both interference lithography and the second lithography exposure wavelength(s).

Alternatively, the interference lithography exposure may be followed by developing the photoresist. After development, the second lithography process may be preceded by applying a second patterning media layer, which may be a different photosensitive media than the first photoresist. The selected second lithography process may determine which patterning media is selected, such as an electron beam sensitive resist or a photosensitive imprint media for imprint patterning. Depending on the selected second lithography process (e.g., optical, imprint, e-beam, etc.), the continuity of the patterned lines 202 (FIG. 2) in the first photoresist 107 may be destroyed by etching portions of the lines 202 defined by the first photoresist 107 through an opening in the patterned media produced by second layer processing.

Alignment

An existing alignment sensor (not shown) on the interference lithography apparatus 100 may align the pattern 200 (FIG. 2) produced by the first lithography process to a previous layer pattern formed by other processes. An existing alignment sensor may be above a wafer and be adapted to sense a mark on the wafer.

Alignment of the second lithography process to the first lithography process may be achieved by either indirect alignment (second lithography process aligns to previous layer pattern by means of existing alignment sensors) or direct alignment (second lithography process aligns to first lithography process pattern 200 directly) by means of a latent image alignment sensor.

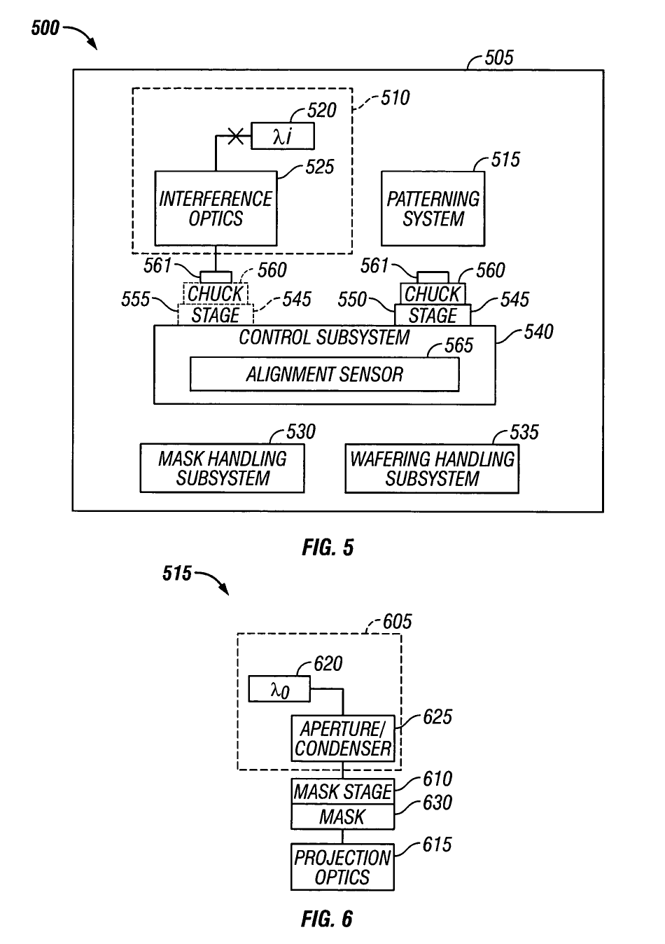

FIG. 5 illustrates a composite optical lithography system 500 with a movable wafer stage 545. The composite optical lithography system 500 may include an environmental enclosure 505, The enclosure 505 encloses an interference lithography system 510 and a second (non-interference) patterning system 515. The interference lithography system 510 may include a collimated coherent radiation source 520 and interference optics 525 to provide interferometric patterning of desired area on a photoresist.

The second patterning system 515 may use one of several techniques to pattern a photoresist. For example, the second patterning system 515 may be an e-beam projection system, an imprint printing system, or an optical lithography system. Alternatively, the second patterning system 515 may be a maskless module, such as an electron beam direct write module, an ion beam direct write module, or an optical direct write module.

The two systems 510, 515 may share a common mask handling subsystem 530, a common wafer handling subsystem 535, a common control subsystem 540, and a common stage 545. The mask handling subsystem 530 may position a mask in the system 500. The wafer handling subsystem 535 may position a wafer 561 in the system 500. The control subsystem 540 may regulate one or more properties or devices of system 500 over time. For example, the control subsystem 540 may regulate the position, alignment or operation of a device in system 500. The control subsystem 540 may also regulate a radiation dose, focus, temperature or other environmental qualities within environmental enclosure 505.

The control subsystem 540 can also translate the stage 545 between a first exposure stage position 555 and a second exposure stage position 550. The stage 545 includes a wafer chuck 560 for gripping a wafer 561. At the first position 555, the stage 545 and the chuck 560 may present a gripped wafer 561 to the interference lithography system 510 for interferometric patterning. At the second position 550, the stage 545 and the chuck 560 may present the gripped wafer 561 to the second patterning system 515 for patterning.

To ensure the proper positioning of a wafer 561 by the chuck 560 and the stage 545, the control subsystem 540 may include an alignment sensor 565. The alignment sensor 565 may transduce and control the position of the wafer 561 (e.g., using wafer alignment marks) to align a pattern formed by the second patterning system 515 with a pattern formed by the interference lithography system 510. Such positioning may be used when introducing irregularity into a repeating array of interferometric features, as discussed above.

FIG. 6 shows an optical lithographic implementation of the second patterning system 515. In particular, the second patterning system 515 may be a step-and-repeat projection system. Such a patterning system 515 may include an illuminator 605, a mask stage 610, a mask 630 and projection optics 615. The illuminator 605 may include a radiation source 620 and an aperture/condenser 625. The radiation source 620 may be the same as radiation source 520 in FIG. 5. Alternatively, the radiation source 620 may be a separate device. The radiation source 620 may emit radiation at the same or at a different wavelength as the radiation source 520.

The aperture/condenser 625 may include one or more devices for collecting, collimating, filtering, and focusing the emitted radiation from the radiation source 520 to increase the uniformity of illumination upon mask stage 610. The mask stage 610 may support a mask 630 in the illumination path. The projection optics 615 may reduce image size. The projection optics 615 may include a filtering projection lens. As the stage 545 translates a gripped wafer 561 for exposure by the illuminator 605 through mask stage 610 and projection optics 615, the alignment sensor 565 may ensure that the exposures are aligned with a repeating array 200 of interferometric features to introduce irregularity into the repeating array 200.

FIG. 8 shows a process 800 for generating a layout of a mask for the second lithography process described above. The process 800 may be performed by one or more actors (such as a device manufacturer, a mask manufacturer, or a foundry) acting alone or in concert. The process 800 may also be performed in whole or in part by a data processing device executing a set of machine-readable instructions.

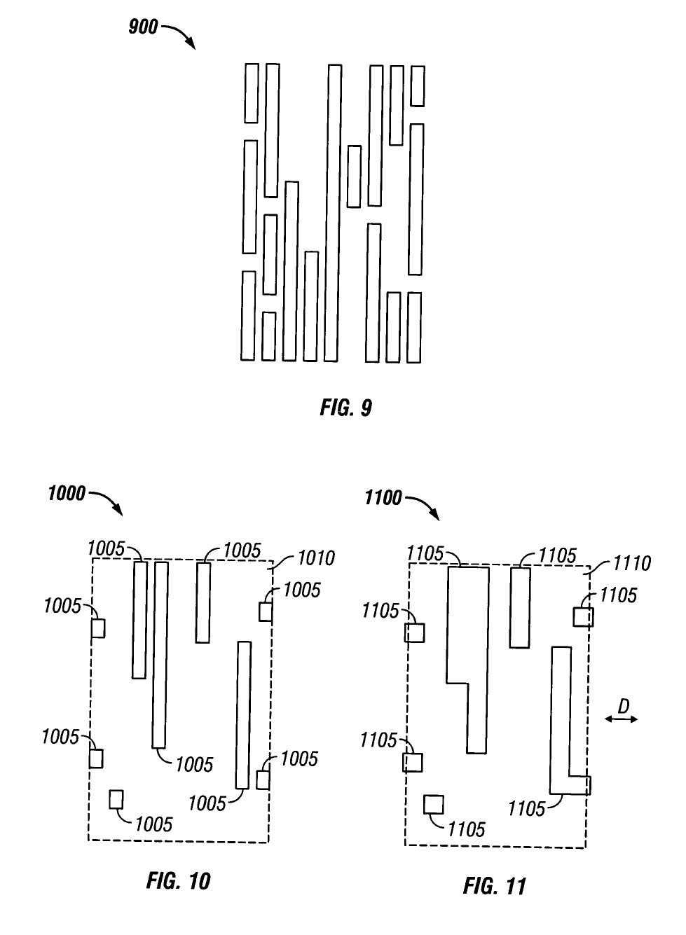

The actor performing the process 800 receives a design layout at 805. The design layout is an intended physical design of a layout piece or substrate after processing. FIGS. 3A and 9 show examples of such design layouts 300, 900. The design layout 300, 900 may be received in a machine-readable form. The physical design of the layout 300, 900 may include a collection of trenches and lands between the trenches. The trenches and lands may be linear and parallel. The trenches and lands need not repeat regularly across the entire layout piece. For example, the continuity of one or both of trenches and lands may be cut at arbitrary positions in the layout 300, 900.

Returning to FIG. 8, the actor performing the process 800 may also receive a pattern array layout 200 of alternating, parallel lines 202 and spaces 204 (FIG. 2) at 810. The pattern array layout 200 may be formed on a photoresist 107 by interferometric lithography techniques, i.e., interference of radiation. The pattern array layout 200 may be received in a machine-readable form.

Returning to FIG. 8, the actor may subtract the design layout 900 (FIG. 9) from the pattern array layout 200 (FIG. 2) at 815. The subtraction of the design layout 900 from the pattern array layout 200 may include aligning trenches 332 in the design layout 900 with either lines or spaces in the pattern array layout 200 and determining positions where irregularity in the design layout 900 prevents complete overlap with the pattern array layout 200.

FIGS. 3B and 10 show examples of remainder layouts 330, 1000 that indicate positions where the design layouts 300, 900 do not completely overlap with the pattern array layout 200 (FIG. 2). The remainders layouts 330, 1000 may be in machine-readable form. The subtraction may be Boolean because positions in the remainder layouts 330, 1000 may have only one of two possible states. In particular, the remainder layout 1000 includes expanses of first positions 1005 with a “not overlapped” state and a contiguous expanse of second positions 1010 with an “overlapped” state.

Returning to FIG. 8, the actor may resize expanses of positions in the remainder layout 1000 at 820. The resizing of the remainder layout 1000 may result in a changed machine-readable remainder layout 1100 in FIG. 11. FIG. 11 shows a remainder layout 1100 after such an expansion in a direction D. When the pattern array is an array 200 of parallel lines 202 and spaces 204, the size of expanses 1105 with a present state may be increased in the direction perpendicular to the lines 202 and spaces 204. Some expanses 1105 may merge.

Returning to FIG. 8, the actor may generate a print mask using the remainder layout 1000 in FIG. 10 at 825. The print mask may be generated using the resized remainder layout 1100 of FIG. 11 to create arbitrarily shaped features for introducing irregularity into a repeating array, such as the pattern array 200 (FIG. 2). The generation of the print mask may include generating a machine-readable description of the print mask. The generation of the print mask may also include tangibly embodying the print mask in a mask substrate.

Alternatively, if the second lithography process uses EUV wavelengths, elements of an EUV lithography system, including the mask to be used, may be reflective. The clear (transmissive) areas on a non-EUV mask will be reflective areas on a EUV mask, and opaque (chrome) areas on a non-EUV mask will be absorptive areas on an EUV mask.

A number of embodiments have been described. Nevertheless, it will be understood that various modifications may be made without departing from the spirit and scope of the application. Accordingly, other embodiments are within the scope of the following claims.

1. A system comprising:
a first subsystem to produce a pattern of alternating lines and spaces on a photoresist, the lines having a substantially equal first width, the spaces being exposed to radiation; and
a second subsystem to radiate selected areas of the photoresist, the selected areas exposing portions of the lines to radiation, the selected areas having a second width, the second width being larger than the first width of the lines.

2. The system of claim 1, wherein a pitch of a pattern produced by the second subsystem is greater than a pitch of the pattern of alternating lines and spaces.

3. The system of claim 1, wherein the first subsystem comprises a beamsplitter.

4. The system of claim 1, wherein the first subsystem comprises a diffraction grating.

5. The system of claim 1, wherein the second subsystem comprises a mask-based optical lithography tool.

6. A method comprising:
forming a pattern of alternating lines and spaces on a photoresist, the lines having a first width, the spaces being exposed to radiation;
exposing a portion of at least one line to radiation to break continuity of grating pattern with a pitch being equal to or greater than a pitch of the grating pattern.

7. The method of claim 6, wherein the radiation has a pre-determined wavelength, the grating pattern having a pitch equal to or larger than an exposure wavelength of an interference lithography apparatus divided by two.

8. The method of claim 6, further comprising generating a print mask from Boolean substraction of (a) a final design layout for a given layer from (b) the pattern of alternating lines and spaces.

9. An apparatus comprising:
an interference exposure module to produce a first exposed array of lines on a photosensitive media; and
a second patterning module to produce a second exposure, the second exposure reducing regularity of the array and breaking continuity of lines formed by the interference exposure module.

10. The apparatus of claim 9, further comprising an alignment sensor to align the second exposure produced by the second patterning module to the first exposed array formed by the interference exposure module.

11. The apparatus of claim 9, further comprising a common control system to enable the interference exposure module and second patterning module to provide first and second exposures to the photosensitive media.

12. The apparatus of claim 9, where the interference exposure module comprises an interference lithography module, and the second patterning module comprises a projection optical lithography system, the projection optical lithography system comprising projection optics, a wafer stage, and a mask to reduce regularity in the array created by the interference exposure module.

13. The apparatus of claim 9, where the interference exposure module comprises an interference lithography module, and the second patterning module comprises an imprint system that comprises projection optics, a wafer stage, and a mask to reduce regularity in the array created by the interference exposure module.

14. The apparatus of claim 9, where the interference exposure module comprises an interference lithography module, and the second patterning module comprises an electron projection system that comprises projection optics, a wafer stage, and a mask to reduce regularity in the array created by the interference exposure module.

15. The apparatus of claim 9, where the interference exposure module comprises an interference lithography module, and the second patterning module comprises a maskless module to reduce regularity in the array created by the interference exposure module, projection optics and a wafer stage.

16. The apparatus of claim 15, wherein the maskless module comprises an optical direct write module.

17. The apparatus of claim 15, wherein the maskless module comprises an electron beam direct write module.

18. The apparatus of claim 15, wherein the maskless module comprises an ion beam direct write module.

19. The apparatus of claim 9, where the interference exposure module comprises an interference lithography module, and the second patterning module comprises an X-ray proximity projection system that contains mask necessary to reduce regularity in a pattern created by the interference exposure module, projection optics and a wafer stage.

20. The apparatus of claim 9, where the interference exposure module comprises an interference lithography module, and the second patterning module comprises an imprint patterning that contains a mask to reduce regularity in a pattern created by the interference exposure module, alignment and illumination optics and a wafer stage.
